(19) United States
(12) Patent Application Publication
(10) Pub. No.: US 2025/0089407 A1
(43) Pub. Date: Mar. 13, 2025

(54) MULTI-PLANARITY OF LIGHT EMITTING SURFACES IN LED COMPONENTS

(71) Applicant: CreeLED, Inc., Durham, NC (US)

(72) Inventors: Joseph M. Favale, Jr., Cary, NC (US); Robert David Schmidt, Wake Forest, NC (US)

(21) Appl. No.: 18/244,354

(22) Filed: Sep. 11, 2023

(51) Int. Cl. H01L 33/48; H01L 25/075; H01L 33/60

(52) U.S. Cl. CPC H10H 20/8506; H01L 25/0753; H10H 20/856

(57) ABSTRACT

Light-emitting diode (LED) packages and more particularly LED packages that have LED chips mounted at different angles with respect to each to modify a far-field emission pattern are disclosed. The LED chips in the LED package can either be pitched inwards so that the light emissions from the LED chips generally overlap, or the LED chips can be pitched outwards. The LED chips can be mounted on a floor of a housing that has a plurality of angled surfaces. In other embodiments, the LED chips can be mounted on a platform in the housing that has different angled surfaces. In other embodiments, the LED chips can be mounted on one or more lead frame pins that can be angled, or angled with respect to other lead frame pins. The LED package may also include a light collector or a lens in order to further modify the far-field emission pattern.

### FIELD OF THE DISCLOSURE

The present disclosure relates to light-emitting diode (LED) packages and more particularly to LED packages that have LED chips mounted at different angles with respect to each other.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials. Photons generated by the active region are initiated in all directions.

LED packages have been developed that can provide mechanical support, electrical connections, and encapsulation for LED emitters. Lumiphoric materials, such as phosphors, may also be arranged in close proximity to LED emitters to convert portions of light emissions to different wavelengths. As LED technology continues to be developed for ever-evolving modern applications, challenges exist in keeping up with operating demands for LED packages and related elements of LED packages.

LED packages that contain more than one LED chip typically have the chips mounted at the same angle with respect to each other, where the LED chips may be mounted on a single flat surface. This can lead to a distribution of light that varies depending on the angle at which one observes the LED package. This is especially true for LED packages that contain LED chips that emit light of different colors.

The art continues to seek improved LEDs and solid-state lighting devices having desirable illumination characteristics capable of overcoming challenges associated with conventional lighting devices.

### SUMMARY

The present disclosure relates to light-emitting diode (LED) packages and more particularly to LED packages that have LED chips mounted at different angles with respect to each other in order to modify a far-field pattern overlap from the LED chips that may emit light in different colors. The LED chips in the LED package can either be pitched inwards so that the light emissions from the LED chips generally overlap, or the LED chips can be pitched outwards. The LED chips can be mounted on a floor of a housing that has a plurality of angled surfaces. In other embodiments, the LED chips can be mounted on a platform in the housing that has different angled surfaces. In other embodiments, the LED chips can be mounted on one or more lead frame pins that can be angled, or angled with respect to other lead frame pins. The LED package may also include a light collector or a lens in order to further modify the far-field emission pattern.

In an embodiment, an LED package can include a housing that forms a recess and a plurality of LED chips arranged within the recess, wherein each LED chip of the plurality of LED chips is pitched at a different angle relative to other LED chips of the plurality of LED chips.

In an embodiment, LED chips of the plurality of LED chips are pitched away from each other such that normal angles of top surfaces of the plurality of LED chips diverge.

In an embodiment, the plurality of LED chips are mounted on a submount platform.

In an embodiment, the submount platform is mounted on lead frame pins of the housing.

In an embodiment, the submount platform is mounted between lead frame pins of the housing.

In an embodiment, the submount platform is integral to the housing between lead frame pins of the housing.

In an embodiment, the submount platform comprises a plurality of surfaces that are angled with respect to one another, and the LED chips of the plurality of LED chips are mounted on respective surfaces of the plurality of surfaces.

In an embodiment, the LED chips of the plurality of LED chips are mounted on a lead frame pin that comprises a plurality of surfaces that are angled with respect to one another.

In an embodiment, the LED chips of the plurality of LED chips are mounted on respective lead frame pins that are angled with respect to one another.

In an embodiment, the LED chips of the plurality of LED chips are pitched towards each other and wherein normal angles of top surfaces of the plurality of LED chips converge.

In an embodiment, the LED chips of the plurality of LED chips are mounted on a lead frame pin that comprises a plurality of surfaces that are angled with respect to one another.

In an embodiment, the LED chips of the plurality of LED chips are mounted on respective lead frame pins that are angled with respect to one another.

In an embodiment, the plurality of LED chips are mounted on a submount platform.

In an embodiment, the submount platform is mounted on lead frame pins of the housing.

In an embodiment, the submount platform is mounted between lead frame pins of the housing.

In an embodiment, the submount platform is integral to the housing between lead frame pins of the housing.

In an embodiment, the LED package also includes a molded lens over the plurality of LED chips and the housing.

In an embodiment, the LED package also includes a light collector arranged at least partially over the plurality of LED chips, wherein the light collector comprises a columnar protrusion at a top of the light collector and wherein the light collector is formed from a first light-transmissive material.

In an embodiment, the LED package also includes a reflective coating covering an entire outer surface of the light collector except for a reduced aperture at a top of the columnar protrusion.

In an embodiment, an LED package includes a housing that forms a recess with a recess floor and one or more recess sidewalls, a lead frame structure extending through the housing, wherein a portion of the lead frame structure is arranged along the recess floor, and a plurality of LED chips arranged within the recess and electrically coupled with the lead frame structure, wherein each LED chip of the plurality of LED chips is pitched at a different angle relative to other LED chips of the plurality of LED chips.

In an embodiment, LED chips of the plurality of LED chips are pitched away from each other such that normal angles of top surfaces of the plurality of LED chips diverge.

In an embodiment, the LED chips of the plurality of LED chips are pitched towards each other and wherein normal angles of top surfaces of the plurality of LED chips converge.

In an embodiment, an LED package includes a housing that forms a recess, a plurality of LED chips arranged within the recess, wherein each LED chip of the plurality of LED chips is pitched at a different angle relative to other LED chips of the plurality of LED chips, and a light collector arranged at least partially over the plurality of LED chips, wherein the light collector comprises an aperture at a top of a columnar protrusion of the light collector and wherein the light collector is formed from a first light-transmissive material, and wherein light from the plurality of LED chips is emitted via the aperture.

In an embodiment, the LED chips of the plurality of LED chips are pitched away from each other such that normal angles of top surfaces of the plurality of LED chips diverge.

In an embodiment, the LED chips of the plurality of LED chips are pitched towards each other and wherein normal angles of top surfaces of the plurality of LED chips converge.

In an embodiment, the LED package also includes a reflective coating on a top surface of the light collector, a fill material over the reflective coating, wherein the fill material is a light-altering material, and a lens over the fill material, the aperture of the light collector, and at least a portion of the housing.

In an embodiment, an LED display includes a display panel and at least one LED package that includes a housing that forms a recess and a plurality of LED chips arranged within the recess, wherein each LED chip of the plurality of LED chips is pitched at a different angle relative to other LED chips of the plurality of LED chips.

In an embodiment, the LED chips of the plurality of LED chips of the LED display are pitched away from each other such that normal angles of top surfaces of the plurality of LED chips do diverge.

In an embodiment, the LED chips of the plurality of LED chips are pitched towards each other and wherein normal angles of top surfaces of the plurality of LED chips converge.

In an embodiment, the at least one LED package of the LED display further includes a light collector arranged at least partially over the plurality of LED chips, wherein the light collector comprises a columnar protrusion at a top of the light collector and wherein the light collector is formed from a first light-transmissive material.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a top view of a light-emitting diode (LED) package that includes a lead frame structure collectively formed by a plurality of leads, a body or housing that encases a portion of the lead frame structure, and a first encapsulation layer that is arranged within a recess that is formed by the housing according to an embodiment of the present disclosure.

FIG. 2 is a cross-sectional view of an LED package with LED chips pitched outwards according to an embodiment of the present disclosure.

FIG. 3 is another cross-sectional view of the LED package of FIG. 2 with a lens according to an embodiment of the present disclosure.

FIG. 4 is a cross-sectional view of an LED package with LED chips pitched inwards according to an embodiment of the present disclosure.

FIG. 5 is another cross-sectional view of the LED package of FIG. 4 with a lens according to an embodiment of the present disclosure.

FIG. 6 is a top-down view of an LED package with LED chips pitched inwards on a plurality of lead frame pins according to an embodiment of the present disclosure.

FIG. 7 is a cross-sectional view of the LED package of FIG. 6 according to an embodiment of the present disclosure.

FIG. 8 is a top-down view of an LED package with LED chips pitched inwards on a lead frame pin according to an embodiment of the present disclosure.

FIG. 9 is a cross-sectional view of the LED package of FIG. 8 according to an embodiment of the present disclosure.

FIG. 10 is a top-down view of an LED package with LED chips pitched outwards on a plurality of lead frame pins according to an embodiment of the present disclosure.

FIG. 11 is cross-sectional view of the LED package of FIG. 10 according to an embodiment of the present disclosure.

FIG. 12 is a top-down view of an LED package with LED chips pitched outwards on a single lead frame pin according to an embodiment of the present disclosure.

FIG. 13 is a cross-sectional view of the LED package of FIG. 12 according to an embodiment of the present disclosure.

FIG. 14 is a top-down view of an LED package with LED chips pitched outwards on a submount platform according to an embodiment of the present disclosure.

FIG. 15 is a cross-sectional view of the LED package of FIG. 14 according to an embodiment of the present disclosure.

FIG. 16 is a cross-sectional view of an LED package with LED chips pitched outwards with a light collector and a lens according to an embodiment of the present disclosure.

FIG. 17 is a cross-sectional view of an LED package with LED chips pitched inwards with a light collector and a lens according to an embodiment of the present disclosure.

FIG. 18 is a top view of a front face of a representative display panel for a LED display that includes a plurality of LED packages according to an embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) packages and more particularly to LED packages that have LED chips mounted at different angles with respect to each other in order to modify a far-field pattern overlap from the LED chips that may emit light in different colors. The LED chips in the LED package can either be pitched inwards so that the light emissions from the LED chips generally overlap, or the LED chips can be pitched outwards. The LED chips can be mounted on a floor of a housing that has a plurality of angled surfaces. In other embodiments, the LED chips can be mounted on a platform in the housing that has different angled surfaces. In other embodiments, the LED chips can be mounted on one or more lead frame pins that can be angled, or angled with respect to other lead frame pins. The LED package may also include a light collector or a lens in order to further modify the far-field emission pattern.

Before delving into specific details of various aspects of the present disclosure, an overview of various elements that may be included in exemplary LED packages is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, SiC, silicon, aluminum nitride (AlN), and GaN.

Different embodiments of the active LED structure can emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. In certain embodiments, the active LED structure may be configured to emit light that is outside the visible spectrum, including one or more portions of the ultraviolet (UV) spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of from 1800K to 10,000K. In certain embodiments, lumiphoric materials having cyan, green, amber, yellow, orange, and/or red peak wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, one or more surfaces of LED chips may be conformally coated with one or more lumiphoric materials, while other surfaces of such LED chips may be devoid of lumiphoric material.

Light emitted by the active layer or region of an LED chip is initiated in all directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of ultraviolet (UV) LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be arranged for flip-chip mounting on another surface.

According to aspects of the present disclosure, LED packages may include one or more elements, such as lumiphoric materials, encapsulants, light-altering materials, lenses, and electrical contacts, among others, that are provided with one or more LED chips. In certain aspects, an LED package may include a support member, such as a submount or a lead frame. Suitable materials for a submount include, but are not limited to, ceramic materials such as aluminum oxide or alumina, AlN, or organic insulators like polyimide (PI) and polyphthalamide (PPA). In other embodiments a submount may comprise a printed circuit board (PCB), sapphire, Si, or any other suitable material. For PCB embodiments, different PCB types can be used such as standard FR-4 PCB, metal core PCB, or any other type of PCB. In still further embodiments, the support structure may embody a lead frame structure.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

In certain applications, LED devices as disclosed herein may be well suited in closely-spaced array applications such automotive lighting, general lighting, and lighting displays. For exterior automotive lighting, multiple LED devices may be arranged under a common lens or optic to provide a single overall emission or emissions that are capable of changing between different emission characteristics. Changing emission characteristics may include toggling between high beam and low beam emissions, adaptively changing emissions, and adjusting correlated color temperatures (CCTs) that correspond with daytime and nighttime running conditions. In general lighting applications, LED devices as disclosed herein may be configured to provide modules, systems, and fixtures that are capable of providing one or more different emission colors or CCT values, such as one or more of warm white (e.g., 1800 Kelvin (K)—3000 K), neutral white (e.g., 3500 K—4500 K), and cool white (5000 K—6500 K). Monochromatic LEDs devices that do not contain phosphor may also be used in this disclosure, in colors such as violet, blue, cyan green, amber, red, photored, and etc. For horticulture lighting applications, LED devices as disclosed herein may be arranged to provide modules, systems, and fixtures that are capable of changing between different emission characteristics that target various growth conditions of different crops.

In certain embodiments, aspects of the present disclosure relate LED packages with lead frame structures that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. The body may be formed on the lead frame structure before singulation so that the individual lead frame portions may be electrically isolated from one another and mechanically supported by the body within an individual LED package. The body may form a cup or a recess in which one or more LED chips may be mounted to the lead frame at a floor of the recess. Portions of the lead frame structure may extend from the recess and through the body to protrude or be accessible outside of the body to provide external electrical connections. An encapsulant material, such as silicone or epoxy, may fill the recess to encapsulate the one or more LED chips.

In certain embodiments, the light-altering material includes both light-reflective material and light-absorbing material suspended in a binder. A weight ratio of the light-reflective material to the binder may comprise a range of about 1:1 to about 2:1. A weight ratio of the light-absorbing material to the binder may comprise a range of about 1:400 to about 1:10. In certain embodiments, a total weight of the light-altering material includes any combination of the binder, the light-reflective material, and the light-absorbing material. In some embodiments, the binder may comprise a weight percent that is in a range of about 10% to about 90% of the total weight of the light-altering material. The light-reflective material may comprise a weight percent that is in a range of about 10% to about 90% of the total weight of the light-altering material. The light-absorbing material may comprise a weight percent that is in a range of about 0% to about 15% of the total weight of the light-altering material.

In further embodiments, the light-absorbing material may comprise a weight percent that is in a range of about greater than 0% to about 15% of the total weight of the light-altering material. In further embodiments, the binder may comprise a weight percent that is in a range of about 25% to about 70% of the total weight of the light-altering material. The light-reflective material may comprise a weight percent that is in a range of about 25% to about 70% of the total weight of the light-altering material. The light-absorbing material may comprise a weight percent that is in a range of about 0% to about 5% of the total weight of the light-altering material. In further embodiments, the light-absorbing material may comprise a weight percent that is in a range of about greater than 0% to about 5% of the total weight of the light-altering material.

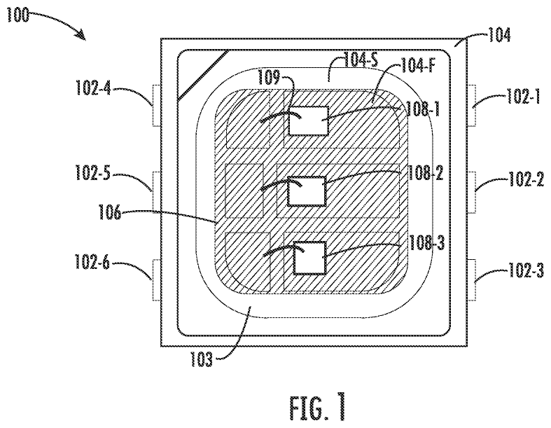

FIG. 1 is a top view of an LED package 100 that includes a lead frame structure collectively formed by a plurality of leads 102-1 to 102-6, a body or housing 104 that encases a portion of the lead frame structure, and an encapsulation layer 106 that is arranged within a recess 103 that is formed by the housing 104. The encapsulation layer 106 can surround and at least partially cover one or more of the LED chips 108-1 to 108-3.

The LED package 100 includes LED chips 108-1 to 108-3 that are mounted on and electrically respectively coupled to the leads 102-1 to 102-3 and electrically coupled to corresponding leads 102-4 to 102-6 by way of wire bonds 109. While a single wire bond 109 is illustrated for each LED chip 108-1 to 108-3, it is understood that various ones of the LED chip 108-1 to 108-3 may embody a lateral structure where a second wire bond may be employed to provide electrical coupling.

In certain aspects, each of the LED chips 108-1 to 108-3 may be configured to emit a different wavelength from the other LED chips. For example, the LED chip 108-1 may be configured to emit red light, the LED chip 108-2 may be configured to emit green light, and the LED chip 108-3 may be configured to emit blue light. In certain embodiments, differences between red, green, and blue emissions may necessitate the LED chip 108-1 being formed of a different material system than the other LED chips 108-2, 108-3. In still further embodiments, the differences between the LED chips 108-1 to 108-3 may include different chip geometries, such as the LED chip 108-1 having a greater thickness than the LED chips 108-2, 108-3. While three LED chips 108-1 to 108-3 are illustrated, the principles disclosed herein are applicable to any number of LED chips within the LED package 100. The recess 103 may include a recess floor 104_{F} and one or more recess sidewalls 104_{S}. The leads 102-1 to 102-6 may be arranged to extend through the housing 104 and a portion of the leads 102-1 to 102-6 may be arranged along or otherwise exposed at the recess floor 104_{F}.

It is to be appreciated that while FIG. 1 depicts the LED chips 108-1 to 108-3 being arranged in a line, in other embodiments, the LED chips 108-1 to 108-3 can be arranged in different configurations such as for example, each chip being arranged equally around a center location of the recess floor 104_{F}. In other embodiments, the arrangement can be based on the color being emitted by the LED chips. For example, an LED chip that emits red light can be placed in the center of the LED package. Since the center chip is likely to have a higher light output efficiency due to the geometry of the LED package 100, and since comparable red LED chips can be more expensive than their green or blue counterparts at comparable absolute intensities, a smaller red LED chip can be used, thereby saving cost.

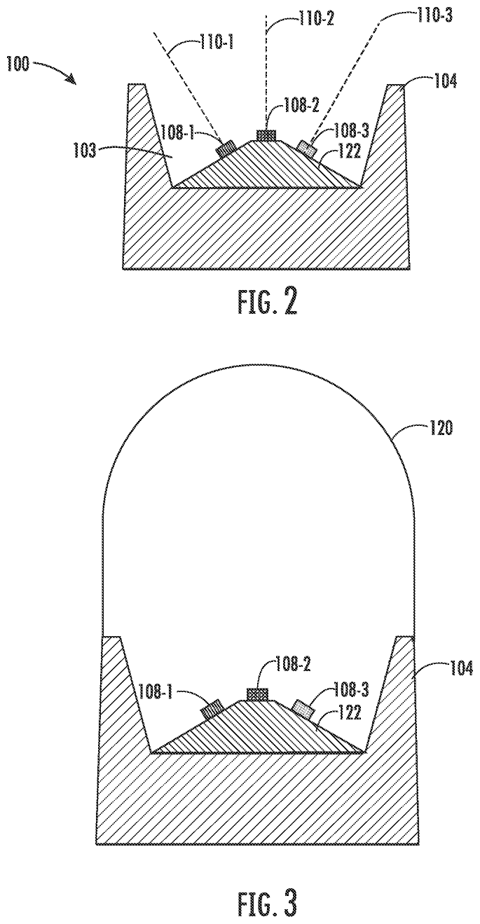

FIG. 2 is a cross-sectional view of an LED package 100 with LED chips 108-1, 108-2, and 108-3 pitched outwards according to an embodiment of the present disclosure.

The LED chips 108-1, 108-2, and 108-3 (collectively referred to as “LED chips 108) can be mounted on a submount platform 122 that is placed on the recess floor 104f of the housing 104, and within the recess 103. The submount platform 122 can have a plurality of angled surfaces, and in the embodiment shown in FIG. 2, three surfaces upon which single LED chips of the LED chips 108 are placed. In an embodiment, the submount platform 122 can be molded and can have any number of surfaces and different angles between the surfaces depending on the desired emission profile and numbers of LED chips 108 to be placed. The submount platform 122 may embody a separate pre-formed element that is attached to the housing 104. In other embodiments, the submount platform 122 may comprise a continuous portion of the housing 104 such that the submount platform 122 and the housing 104 are concurrently formed. The submount platform 122, in various embodiments, can be formed from molded silicone, epoxy, other plastic (e.g., polyphthalamide (PPA), Polycyclohexylenedimethylene terephthalate (PCT)), glass, or ceramic. The submount platform 122 can be transparent, light-reflective or light-absorptive.

The normals 110-1, 110-2, and 110-3 of the LED chips 108 can be adjusted based on the desired emission pattern. For example, the normals 110 can be adjusted so that the angle between normal 110-1 and 110-2 is small to provide just slightly broader illumination than if the LEDs chips 108 were flat mounted on the recess floor. In other embodiments, the angles of the normals 110 with respect to each other can be up to 90 degrees, or even higher depending on the desired emission pattern. In general, however, in an embodiment as shown in FIG. 2, the normal 110-1, 110-2, and 110-3 may generally diverge above the surface of the LED package 100.

FIG. 3 is another cross-sectional view of the LED package of FIG. 2 with a lens 120 according to an embodiment of the present disclosure.

The lens 120 can be placed over the LED chips 108 and submount platform 122. In some embodiments, as shown in FIG. 3 the lens 120 may also be placed over at least a portion of the housing 104 as well.

The lens 120 can be a molded lens that is either formed over the rest of the LED package 100 using a molding process or is formed as a separate element and later fixed to the LED package 100 with an adhesive. The lens 120 can be glass or silicone or another suitable light-transmissive material. The lens 120 can serve to further modify the emission pattern of the LED chips 108 based on a desired emission profile, and adjusting the shape and material of the lens 120 can modify the emission profile further.

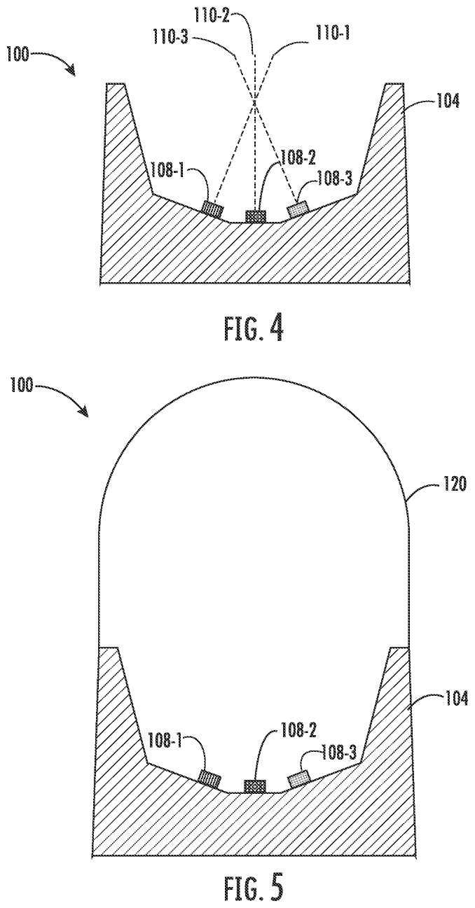

FIG. 4 is a cross-sectional view of an LED package 100 with LED chips 108-1, 108-2, and 108-3 pitched inwards according to an embodiment of the present disclosure.

The LED chips 108 can be mounted on the recess floor that can have a plurality of angled surfaces. The angled surfaces could be formed when the housing 104 is molded or formed. The angled surfaces could also be ground down or formed after the housing 104 is formed. In an embodiment, the recess floor can have any number of surfaces and different angles between the surfaces depending on the desired emission profile and numbers of LED chips 108 to be placed.

The normals 110-1, 110-2, and 110-3 of the LED chips 108-1, 108-2, and 108-3 respectively can be adjusted based on the desired emission pattern. For example, the angled surfaces of the recess floor can be formed such that the normals 110-1, 110-2, and 110-3 intersect or converge at some location away from the LED package 100. It is to be appreciated that while in some embodiments, the normal 110-1, 110-2, and 110-3 may intersect, in other embodiments, the normal may not intersect, but generally converge. In an embodiment, the convergence distance, and thus the angles of the angled surfaces can be set based on the desired emission profile or intended use of the LED package 100.

FIG. 5 is another cross-sectional view of the LED package 100 of FIG. 4 with a lens 120 according to an embodiment of the present disclosure.

The lens 120 can be placed over the LED chips 108. In some embodiments, as shown in FIG. 5 the lens 120 may also be placed over at least a portion of the housing 104 as well.

The lens 120 can be a molded lens that is either formed over the rest of the LED package 100 using a molding process or is formed as a separate element and later fixed to the LED package 100 with an adhesive. The lens 120 can be glass or silicone or another suitable light-transmissive material. The lens 120 can serve to further modify the emission pattern of the LED chips 108 based on a desired emission profile, and adjusting the shape and material of the lens 120 can modify the emission profile further.

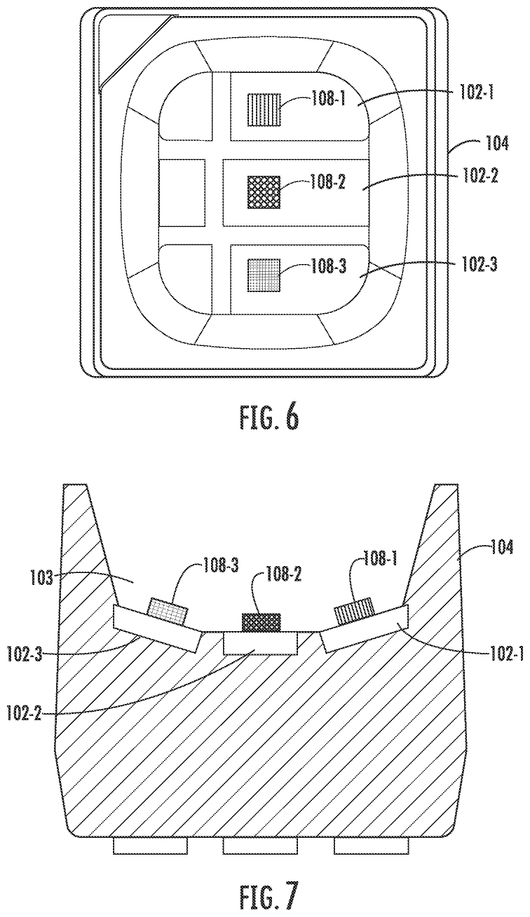

FIG. 6 is a top-down view of an LED package with LED chips pitched inwards on a plurality of lead frame pins according to an embodiment of the present disclosure.

In the LED package 100 of the embodiment shown in FIG. 6, the LED chips 108-1, 108-2, and 108-3 can be pitched inwards or angled inwards such that their normals converge or intersect above the LED package 100, but instead of being mounted on a recess floor of the housing 104, the LED chips 108-1, 108-2, and 108-3 can be mounted on lead frame pins 102-1, 102-2, and 102-3 respectively. The lead frame pins 102-1, 102-2, and 102-3 can themselves be angled or pitched towards each other as seen in FIG. 7, which is a cross sectional view of the embodiment shown in FIG. 6. It is to be appreciated that in some embodiments, the middle pin 102-2 may be recessed further below inner edge of outer pins 102-1 and 102-3.

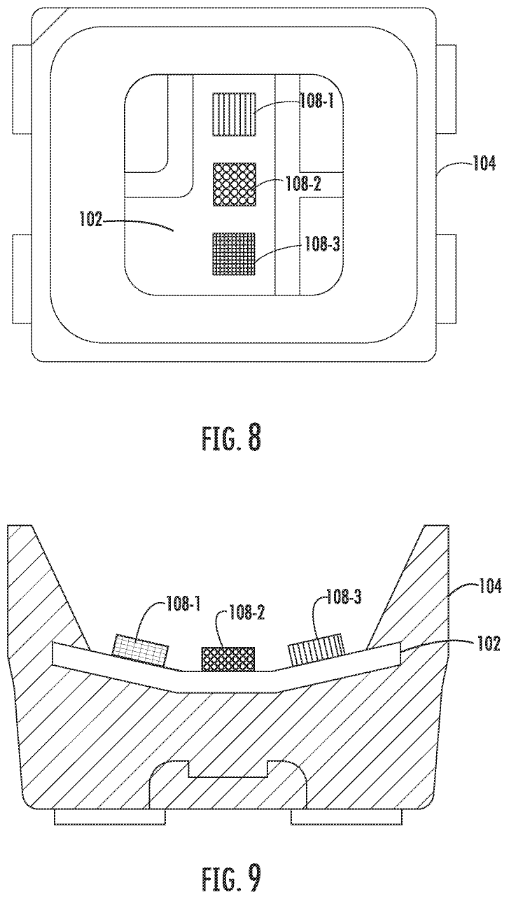

FIG. 8 is a top-down view of an LED package 100 with LED chips 108-1, 108-2, and 108-3 pitched inwards on a single lead frame pin 102 according to an embodiment of the present disclosure. In this embodiment, the lead frame pin 102 can be formed such that it includes several angled surfaces as shown in the cross-sectional view in FIG. 9, where each of the LED chips 108-1, 108-2, and 108-3 are mounted on respective angled surfaces of the lead frame pin 102.

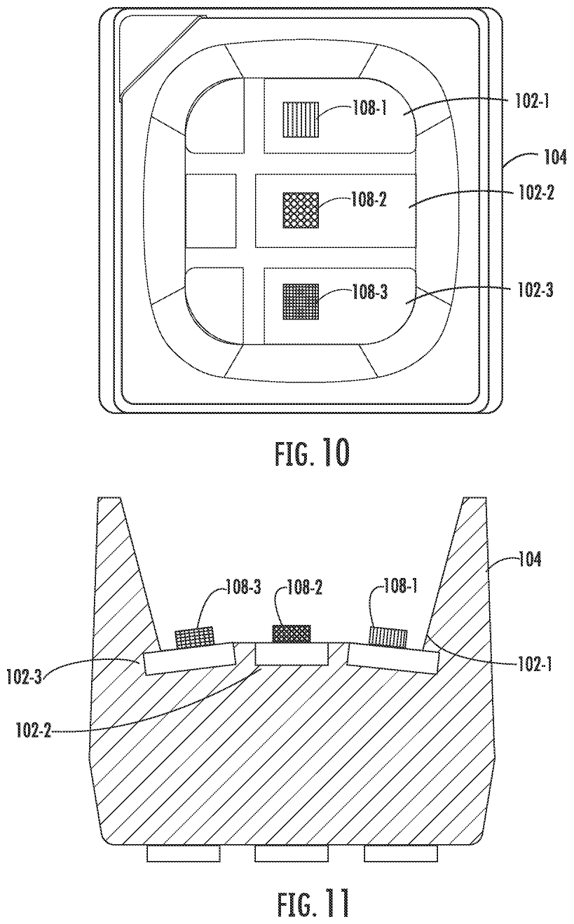

FIG. 10 is a top-down view of an LED package with LED chips pitched outwards on a plurality of lead frame pins according to an embodiment of the present disclosure.

In the LED package 100 of the embodiment shown in FIG. 10, the LED chips 108-1, 108-2, and 108-3 can be pitched outwards or angled outwards to increase the spread of the light emitted relative to an embodiment where all the LED chips 108 were mounted in the same plane. The result is that in the case of the LED chips 108 being different colors, the overall color balance of the light emitted by the LED package 100 can vary depending on the viewing angle. Instead of being mounted on a recess floor of the housing 104, the LED chips 108-1, 108-2, and 108-3 can be mounted on lead frame pins 102-1, 102-2, and 102-3 respectively. The lead frame pins 102-1, 102-2, and 102-3 can themselves be angled or pitched outwards away from each other as seen in FIG. 11, which is a cross sectional view of the embodiment shown in FIG. 10. It is to be appreciated that in some embodiments, the middle pin 102-2 may be above the inner edge of outer pins 102-1 and 102-3.

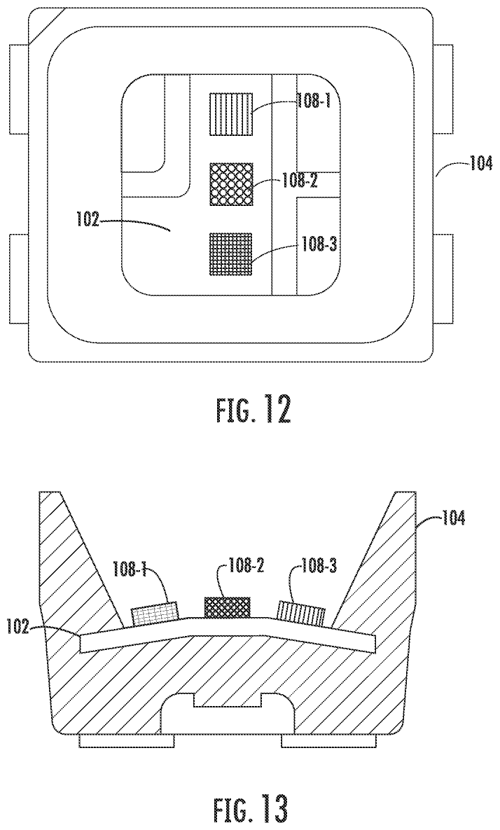

FIG. 12 is a top-down view of an LED package 100 with LED chips 108-1, 108-2, and 108-3 pitched outwards on a single lead frame pin 102 according to an embodiment of the present disclosure. In this embodiment, the lead frame pin 102 can be formed such that it includes several angled surfaces as shown in the cross-sectional view in FIG. 13, where each of the LED chips 108-1, 108-2, and 108-3 are mounted on respective angled surfaces of the lead frame pin 102.

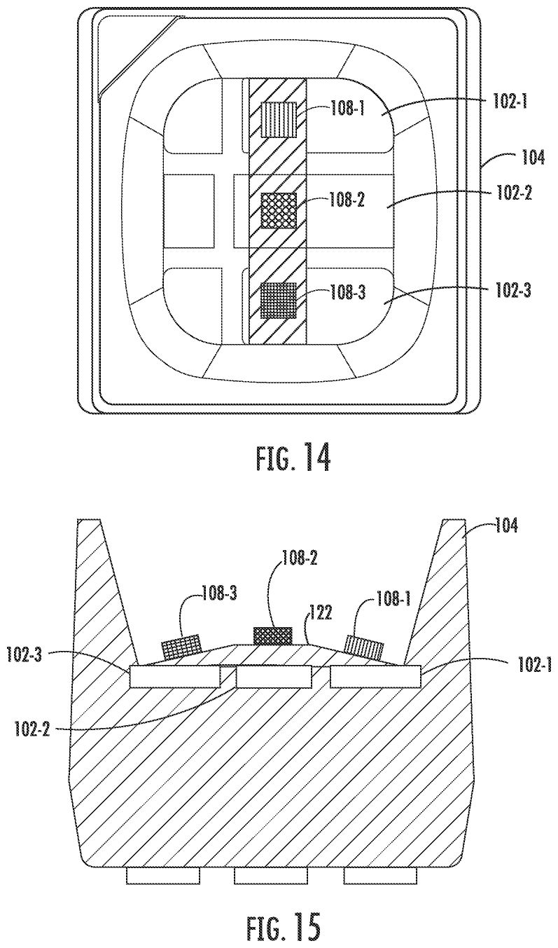

FIG. 14 is a top-down view of an LED package with LED chips pitched outwards that are mounted on a submount frame over a plurality of lead frame pins according to an embodiment of the present disclosure.

In the LED package 100 of the embodiment shown in FIG. 10, the LED chips 108-1, 108-2, and 108-3 can be mounted on a submount platform 122 that is arranged over lead frame pins 102-1, 102-2, and 102-3. The submount platform 122 can have a plurality of angled surfaces, and in the embodiment shown in FIG. 15, which is a cross-sectional view to the embodiment in FIG. 14, three surfaces upon which single LED chips of the LED chips 108 are placed. In an embodiment, the submount platform 122 can be molded and can have any number of surfaces and different angles between the surfaces depending on the desired emission profile and numbers of LED chips 108 to be placed.

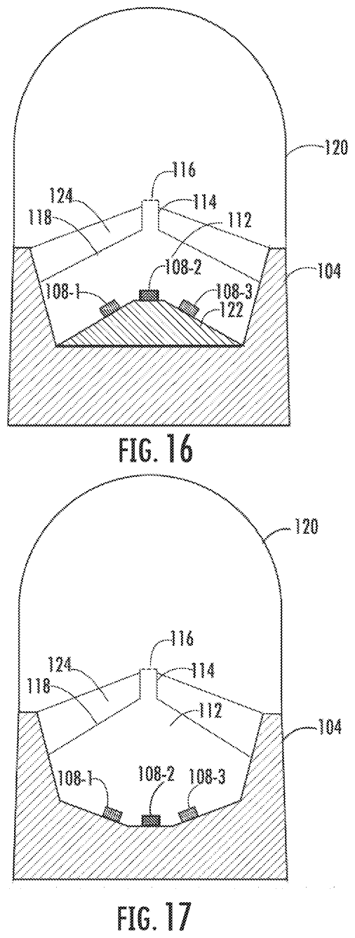

FIG. 16 is cross-sectional view of an LED package with LED chips pitched outwards with a light collector and a lens according to an embodiment of the present disclosure.

The light collector 112 can be placed over the LED chips 108-1 to 108-3. The light collector 112 can be formed from epoxy, silicone, or some other light-transmissive material. The light collector 112 can be coated with a reflective coating 118 on the top surface of the light collector 112 except for an uncoated aperture 116 at or near the apex, center, or top of the light collector 112. Light emitted by the LED chips 108-1 to 108-3 can enter the light collector 112, and reflect one or more times off the reflective coating 118, thereby mixing within the light collector before eventually exiting the light collector 112 via the aperture 116. The light mixing within the light collector 112 before exiting via the aperture 116 results in light from each of the LED chips 108-1, 108-02, and 108-3 appearing as if the light originated from a single emission point or area (the aperture 110) instead of from 3 separate and distinct locations, thereby improving the emission pattern and reducing color over angle shifts of the LED package 100. It is to be appreciated that when the present disclosure refers to a single emission point, this is not a point in a mathematical sense, but instead refers to a single emission source (e.g., an LED chip or the output of the plurality of LED chips from the aperture 116. In this sense, point can be a term for a light source that is smaller than the LED package or system being described, and the size can depend on the overall system.

In an embodiment, the reflective coating 118 on the light collector 112 can be a metal or metal oxide that is deposited or layered on the light collector 112. For example, the reflective coating 118 could be metal cladding (e.g., silver, aluminum, etc.) in one embodiment, or be a TiO₂ surface deposition, paint, or coating in another embodiment. In another embodiment, the reflective coating 112 could comprise diffuse reflectors from either texturing or particulates in a medium (e.g., pigments). Additionally, the reflective coating 112 could be a fill layer of epoxy or silicone that comprises reflectors such as TiO₂. The choice of material for the reflective coating can be based on the desired emission characteristics of the LED package, with more highly reflective materials being used when higher intensity light emissions are desired. In the embodiment shown in FIG. 16, the reflective coating 118 is depicted as a thin coating on the surface of the light collector 112, but in other embodiments, the reflecting coating 118 could be a thicker layer as described above.

In an embodiment, the light collector 112 can have a stemmed portion 114 which can have a diameter roughly equivalent to the diameter of the aperture 116. The stemmed portion 114 can be a protrusion in the shape of a cylinder that extends from a top, center, or apex of the light collector 112. In other embodiments, the stemmed portion 114 can have a shape other than being cylindrical.

The height of the stemmed portion 114 can be such that there is no line of sight or a reduced line of sight from LED chips 108-3 and 108-1 to the aperture 116, so that at least a majority of light emitted by LED chips 108-3 and 108-1 reflect off one of the other surfaces such as the reflective coating 118 or the recess floor at least one time before exiting the light collector 112 via the aperture 116. The height of the stemmed portion 114 can thus vary depending on both the diameter of the aperture 116 and/or the distribution or placement of the LED chips 108-1, 108-02, and 108-3 within the housing 104. For example, if the height of the stemmed portion were lowered, the width of the aperture 116 would decrease so that this condition of light reflecting at least one before exiting would be met.

In an embodiment, a fill material 124 can be added over the reflective coating 118 on the top surface of the light collector 112. In various embodiments, the fill material 124 can include light-altering materials, such as light-reflective materials or light-absorptive materials that either reflect or block or reduce light that may pass through or around the reflective coating 118 the light collector, and can ensure that the majority of the light emitted by the LED package 100 is via the aperture 116. The fill material can be an epoxy or silicone that has a composition configured to be light reflecting or blocking. In an embodiment, the fill material 124 can leave at least a portion of the light collector 112 around the aperture 116 uncovered. Additionally, in various embodiments, the fill material 124 and the reflective coating 118 can be partially transmissive.

A lens 120 can also be placed over the fill material 124 and the light collector 112 so that an emission pattern of light emitted from the aperture 116 can be further modified.

FIG. 17 is cross-sectional view of an LED package 100 with LED chips 108-1, 108-2, and 108-3 pitched inwards with the light collector 112 and a lens 120 similar to the embodiment shown in FIG. 16 according to an embodiment of the present disclosure.

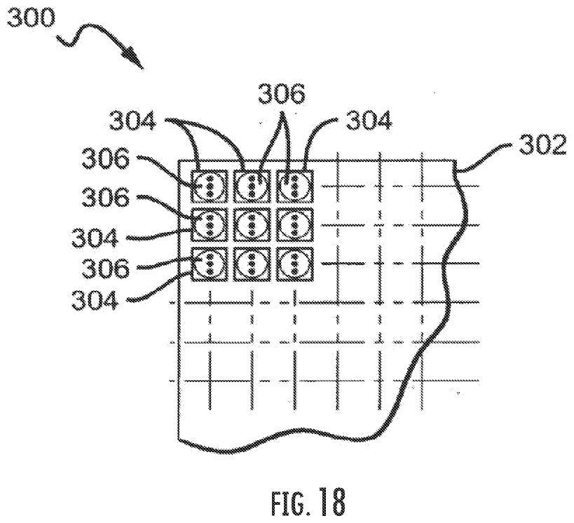

With reference to FIG. 18, there is shown in schematic form a portion of an LED display screen 300, for example, an indoor and/or outdoor screen comprising, in general terms, a driver printed circuit board (PCB) 302 carrying a large number of surface-mount devices (SMD) 304 arranged in rows and columns, each SMD defining a pixel. The SMDs 304 may comprise devices such as the embodiments shown in FIGS. 1-17. The SMD devices 304 are electrically connected to traces or pads on the PCB 302 connected to respond to appropriate electrical signal processing and driver circuitry (not shown). As disclosed above, it is to be appreciated that while FIG. 18 depicts the LED chips 306 being arranged in a line, in other embodiments, the LED chips 306 can be arranged in different configurations. It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package, comprising:
a housing that forms a recess; and
a plurality of LED chips arranged within the recess, wherein each LED chip of the plurality of LED chips is pitched at a different angle relative to other LED chips of the plurality of LED chips.

2. The LED package of claim 1, wherein LED chips of the plurality of LED chips are pitched away from each other such that normal angles of top surfaces of the plurality of LED chips diverge.

3. The LED package of claim 2, wherein the plurality of LED chips are mounted on a submount platform.

4. The LED package of claim 3, wherein the submount platform is mounted on lead frame pins of the housing.

5. The LED package of claim 3, wherein the submount platform is mounted between lead frame pins of the housing.

6. The LED package of claim 3, wherein the submount platform is integral to the housing between lead frame pins of the housing.

7. The LED package of claim 3, wherein the submount platform comprises a plurality of surfaces that are angled with respect to one another, and the LED chips of the plurality of LED chips are mounted on respective surfaces of the plurality of surfaces.

8. The LED package of claim 2, wherein the LED chips of the plurality of LED chips are mounted on a lead frame pin that comprises a plurality of surfaces that are angled with respect to one another.

9. The LED package of claim 2, wherein the LED chips of the plurality of LED chips are mounted on respective lead frame pins that are angled with respect to one another.

10. The LED package of claim 1, wherein the LED chips of the plurality of LED chips are pitched towards each other and wherein normal angles of top surfaces of the plurality of LED chips converge.

11. The LED package of claim 10, wherein the LED chips of the plurality of LED chips are mounted on a lead frame pin that comprises a plurality of surfaces that are angled with respect to one another.

12. The LED package of claim 11, wherein the LED chips of the plurality of LED chips are mounted on respective lead frame pins that are angled with respect to one another.

13. The LED package of claim 10, wherein the plurality of LED chips are mounted on a submount platform.

14. The LED package of claim 13, wherein the submount platform is mounted on lead frame pins of the housing.

15. The LED package of claim 13, wherein the submount platform is mounted between lead frame pins of the housing.

16. The LED package of claim 13, wherein the submount platform is integral to the housing between lead frame pins of the housing.

17. The LED package of claim 1, further comprising:
a molded lens over the plurality of LED chips and the housing.

18. The LED package of claim 1, further comprising:
a light collector arranged at least partially over the plurality of LED chips, wherein the light collector comprises a columnar protrusion at a top of the light collector and wherein the light collector is formed from a first light-transmissive material.

19. The LED package of claim 18, further comprising:
a reflective coating covering an entire outer surface of the light collector except for a reduced aperture at a top of the columnar protrusion.

20. A light-emitting diode (LED) package comprising:
a housing that forms a recess with a recess floor and one or more recess sidewalls;
a lead frame structure extending through the housing, wherein a portion of the lead frame structure is arranged along the recess floor; and
a plurality of LED chips arranged within the recess and electrically coupled with the lead frame structure, wherein each LED chip of the plurality of LED chips is pitched at a different angle relative to other LED chips of the plurality of LED chips.

21. The LED package of claim 20, wherein LED chips of the plurality of LED chips are pitched away from each other such that normal angles of top surfaces of the plurality of LED chips diverge.

22. The LED package of claim 20, wherein the LED chips of the plurality of LED chips are pitched towards each other and wherein normal angles of top surfaces of the plurality of LED chips converge.

23. A light-emitting diode (LED) package comprising:
a housing that forms a recess;
a plurality of LED chips arranged within the recess, wherein each LED chip of the plurality of LED chips is pitched at a different angle relative to other LED chips of the plurality of LED chips; and
a light collector arranged at least partially over the plurality of LED chips, wherein the light collector comprises an aperture at a top of a columnar protrusion of the light collector and wherein the light collector is formed from a first light-transmissive material, and wherein light from the plurality of LED chips is emitted via the aperture.

24. The LED package of claim 23, wherein LED chips of the plurality of LED chips are pitched away from each other such that normal angles of top surfaces of the plurality of LED chips diverge.

25. The LED package of claim 23, wherein the LED chips of the plurality of LED chips are pitched towards each other and wherein normal angles of top surfaces of the plurality of LED chips converge.

26. The LED package of claim 23, further comprising:
a reflective coating on a top surface of the light collector;
a fill material over the reflective coating, wherein the fill material is a light-altering material; and
a lens over the fill material, the aperture of the light collector, and at least a portion of the housing.

27. A light-emitting diode (LED) display comprising:
a display panel; and
at least one LED package comprising:
a housing that forms a recess; and
a plurality of LED chips arranged within the recess, wherein each LED chip of the plurality of LED chips is pitched at a different angle relative to other LED chips of the plurality of LED chips.

28. The LED display of claim 27, wherein LED chips of the plurality of LED chips are pitched away from each other such that normal angles of top surfaces of the plurality of LED chips do diverge.

29. The LED display of claim 27, wherein the LED chips of the plurality of LED chips are pitched towards each other and wherein normal angles of top surfaces of the plurality of LED chips converge.

30. The LED display of claim 27, wherein the at least one LED package further comprises:
a light collector arranged at least partially over the plurality of LED chips, wherein the light collector comprises a columnar protrusion at a top of the light collector and wherein the light collector is formed from a first light-transmissive material.
